(19) United States
(12) Patent Application Publication
(10) Pub. No.: US 2025/0031389 A1
(43) Pub. Date: Jan. 23, 2025

(54) CAPACITOR DEVICE AND MANUFACTURING METHOD THEREOF

(71) Applicant: Fujian Jinhua Integrated Circuit Co., Ltd., Quanzhou City (CN)

(72) Inventors: Bingxing Wu, Quanzhou City (CN); Jung-Hua Chen, Quanzhou City (CN); Wei-Ming Hsiao, Quanzhou City (CN); Yu-Cheng Tung, Quanzhou City (CN); Qiangwei Xu, Quanzhou City (CN)

(73) Assignee: Fujian Jinhua Integrated Circuit Co., Ltd., Quanzhou City (CN)

(21) Appl. No.: 18/508,191

(22) Filed: Nov. 13, 2023

(30) Foreign Application Priority Data
Jul. 18, 2023 (CN) 202310882382.4

(51) Int. Cl. H01G 4/005; H10B 12/00

(52) U.S. Cl. CPC H01L 28/91; H01L 28/75; H10B 12/0335; H10B 12/31

(57) ABSTRACT

A capacitor device and a manufacturing method thereof are disclosed in the present invention. The capacitor device includes pad structures, bottom electrodes, a top electrode, and a dielectric layer. The bottom electrodes are disposed on the pad structures, respectively. The top electrode is disposed on the bottom electrodes. The dielectric layer is disposed between the top electrode and the bottom electrodes. The top electrode includes at least one void. The manufacturing throughput of the manufacturing method of the memory device may be enhanced accordingly.

### BACKGROUND OF THE INVENTION

### 1. Field of the Invention

The present invention relates to a memory device and a manufacturing method thereof, and more particularly, to a capacitor device including at least one void and a manufacturing method thereof.

### 2. Description of the Prior Art

The memory device, such as dynamic random access memory (DRAM), generally includes a storage capacitor and a storage transistor electrically connected with the storage capacitor. The storage capacitor is used to store electric charge as information, and the storage transistor may be electrically connected with the storage capacitor via a node contact structure. For product demands, the density of memory cells needs to be continuously increased, resulting in increasing difficulty and complexity in related manufacturing processes and designs and resulting in increased production costs. Therefore, the production efficiency needs to be enhanced and the production cost needs to be reduced still by improving structural design and/or manufacturing processes.

### SUMMARY OF THE INVENTION

A capacitor device and a manufacturing method thereof are provided in the present invention. At least one void is disposed in one electrically conductive layer of a top electrode having a multi-layer structure for reducing negative influence of the void on the top electrode while increasing the manufacturing throughput of the manufacturing method.

According to an embodiment of the present invention, a capacitor device is provided. The capacitor device includes pad structures, bottom electrodes, a top electrode, and a dielectric layer. The bottom electrodes are disposed on the pad structures, respectively. The top electrode is disposed on the bottom electrodes. The dielectric layer is disposed between the top electrode and the bottom electrodes. The top electrode includes at least one void.

According to an embodiment of the present invention, a manufacturing method of a capacitor device is provided. The manufacturing method includes the following steps. A bottom electrode is formed on a pad structure. A top electrode and a dielectric layer are formed. The top electrode is disposed on the bottom electrode. The dielectric layer is disposed between the top electrode and the bottom electrode. The top electrode includes at least one void.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a schematic drawing illustrating a memory device according to a first embodiment of the present invention.

FIGS. 2-9 are schematic drawings illustrating a manufacturing method of a memory device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, and FIG. 9 is a schematic drawing in a step subsequent to FIG. 8.

FIG. 10 is a schematic drawing illustrating a memory device according to a second embodiment of the present invention.

FIG. 11 is a schematic drawing illustrating a memory device according to a third embodiment of the present invention.

FIG. 12 is a schematic drawing illustrating a memory device according to a fourth embodiment of the present invention.

FIG. 13 is a schematic drawing illustrating a memory device according to a fifth embodiment of the present invention.

FIG. 14 is a schematic drawing illustrating a memory device according to a sixth embodiment of the present invention.

FIG. 15 is a schematic drawing illustrating a memory device according to a seventh embodiment of the present invention.

### DETAILED DESCRIPTION

To provide a better understanding of the presented invention for those skilled in the technical field of the present invention, several preferred embodiments of the present invention are enumerated below, together with the accompanying drawings, to describe the technical solutions and desired effects of the present invention in detail. Those skilled in the art may refer to the following embodiments and replace, reorganize, and mix features in several different embodiments to complete other embodiments without departing from the spirit of the present invention

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

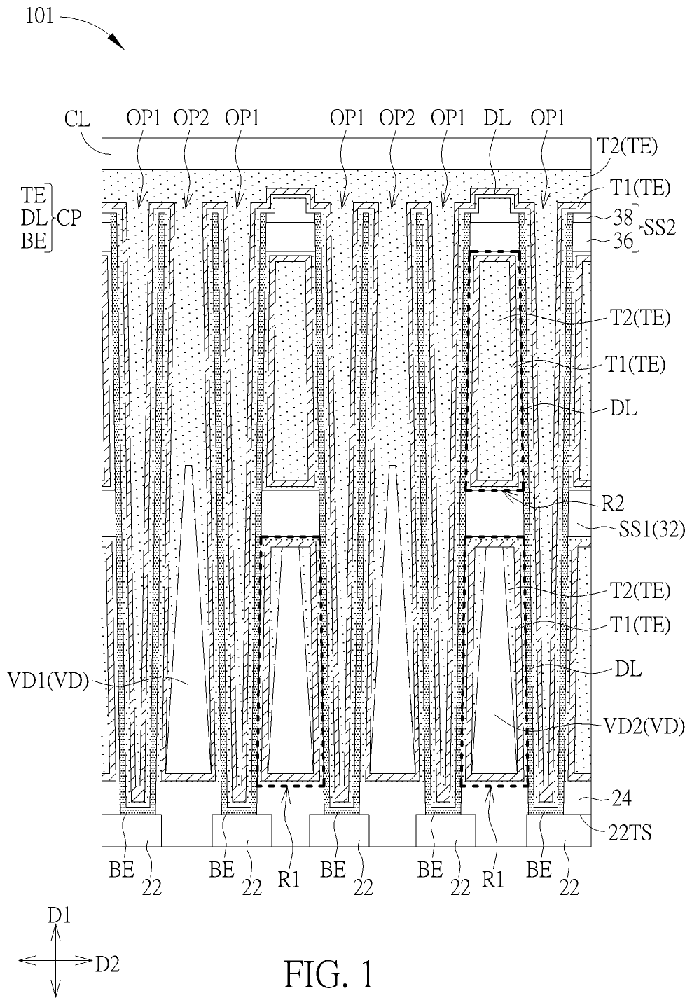

Please refer to FIG. 1. FIG. 1 is a schematic drawing illustrating a memory device 101 according to a first embodiment of the present invention. As shown in FIG. 1, the memory device 101 includes a node contact structure 22 and a capacitor structure CP. The capacitor structure CP is disposed on the node contact structure 22, and the capacitor structure CP includes a bottom electrode BE, a top electrode TE, and a dielectric layer DL. The bottom electrode BE is disposed on the node contact structure 22, the top electrode is TE disposed on the bottom electrode BE, and the dielectric layer DL is disposed between the top electrode TE and the bottom electrode BE. The top electrode TE includes a first conductive layer T1 and a second conductive layer T2. The first conductive layer T1 is disposed on the dielectric layer DL, the second conductive layer T2 is disposed on the first conductive layer T1, and at least one void VD is disposed in the second conductive layer T2. The connection between the dielectric layer DL and the first conductive layer T1 of the top electrode TE is not affected because the void VD is located in the second conductive layer T2 of the top electrode TE, and voids formed in the top electrode TE of the capacitor structure CP are acceptable without influencing the operation of the capacitor structure CP and the capacitance of the capacitor structure CP accordingly. Therefore, the capacitor structure CP may be formed by a faster manufacturing process, and the throughput of the related manufacturing equipment may be improved, the manufacturing capacity may be enhanced, and/or the manufacturing cost may be reduced relatively. The memory device disclosed in each embodiment of the present invention may be regarded as a capacitor device also, the node contact structure 22 may be regarded as a pad structure, and the top electrode TE includes at least one void.

In some embodiments, the memory device 101 may include a plurality of the node contact structures 22, and the capacitor structure CP may include a plurality of the bottom electrodes BE, but not limited thereto. The capacitor structure CP may be disposed on the node contact structures 22, and the bottom electrodes BE may be disposed on the node contact structures 22, respectively. For instance, the bottom electrodes BE may be separated from one another without being directly connected with one another, and each of the bottom electrodes BE may be respectively connected with one of the node contact structures 22 and electrically connected with this corresponding node contact structure 22. In addition, the top electrode TE may be disposed on the bottom electrodes BE, and the dielectric layer DL may be disposed between the top electrode TE and the bottom electrodes BE. Additionally, in some embodiments, the memory device 101 may further include an isolation structure 24 disposed adjacent to the node contact structures 22, the isolation structure 24 may be partly located on each of the node contact structures 22 in the vertical direction D1, and the isolation structure 24 may be partly located between the node contact structures 22 adjacent to each other.

In some embodiments, the isolation structure 24 and the node contact structures 22 may be disposed on a semiconductor substrate (not illustrated), and a transistor structure (not illustrated) may be disposed on the semiconductor substrate and electrically connected with the node contact structure 22, but not limited thereto. In addition, the vertical direction D1 described above may be regarded as a thickness direction of the semiconductor substrate and/or a thickness direction of the isolation structure 24, and horizontal directions (such as a horizontal direction D2, but not limited thereto) may be substantially orthogonal to the vertical direction D1. In this description, a distance between a top surface 22TS of the node contact structure 22 and a relatively higher location and/or a relatively higher part in the vertical direction D1 may be greater than a distance between the top surface 22TS of the node contact structure 22 and a relatively lower location and/or a relatively lower part in the vertical direction D1, and the bottom or a lower portion of each component may be closer to the top surface 22TS of the node contact structure 22 in the vertical direction D1 than the top or an upper portion of this component, but not limited thereto. Additionally, in this description a top portion and a top surface of a specific component may include the topmost portion and the topmost surface of this component in the vertical direction D1, and a bottom portion and a bottom surface of a specific component may include the bottommost portion and the bottommost surface of this component in the vertical direction D1, but not limited thereto. Additionally, in this description, the condition that a certain component is disposed between two other components in a specific direction may include a condition that the certain component is sandwiched between the two other components in the specific direction, but not limited thereto.

In some embodiments, the memory device 101 may further include a first supporting layer 32 and a second supporting layer 36. The first supporting layer 32 may be disposed above the isolation structure 24 in the vertical direction D1, and the second supporting layer 36 may be disposed above the first supporting layer 32 in the vertical direction D1. The dielectric layer DL and the top electrode TE may be partly disposed between the first supporting layer 32 and the isolation structure 24, and the dielectric layer DL and the top electrode TE may be partly disposed between the second supporting layer 36 and the first supporting layer 32. In some embodiments, a first region R1 may be located between the first supporting layer 32 and the isolation structure 24 in the vertical direction D1, a second region R2 may be located between the second supporting layer 36 and the first supporting layer 32 in the vertical direction D1, and the first region R1 and the second region R2 may be located between the bottom electrodes BE adjacent to each other in the horizontal direction. A part of the dielectric layer DL and a part of the top electrode TE may be disposed in the first region R1, and another part of the dielectric layer DL and another part of the top electrode TE may be disposed in the second region R2. Additionally, in some embodiments, each of the bottom electrodes BE may be disposed in an opening OP1, the first supporting layer 32 and the second supporting layer 36 may support the sidewall of the bottom electrode BE laterally, another opening OP2 may be at least partially located between the bottom electrodes BE adjacent to each other, and there is not any supporting layer (such as the first supporting layer 32 and the second supporting layer 36) in the opening OP2, but not limited thereto. In some embodiments, in a cross-sectional diagram of the memory device 101, the opening OP1 may have an inverted trapezoidal structure with narrow bottom and wide top, each of the bottom electrodes BE may have a V-shaped structure or U-shaped structure, and the opening OP2 may have a trapezoidal structure with wide bottom and narrow top, but not limited thereto. A part of the dielectric layer DL and a part of the top electrode TE may be disposed in the opening OP1, and another part of the dielectric layer DL and another part of the top electrode TE may be disposed in the opening OP2.

In some embodiments, the void VD disposed in the second conductive layer T2 may include a seam and/or an air gap, but not limited thereto. In some embodiments, the top electrode TE may be partly disposed between two of the bottom electrodes BE, and the void VD may be disposed and/or formed between two of the bottom electrodes BE adjacent to each other. In some embodiments, the void VD may be disposed and/or formed in the second conductive layer T2 of the top electrode TE located between the first supporting layer 32 and the isolation structure 24. For example, in some embodiments, the voids VD in the memory device 101 may include a void VD1 disposed in the opening OP2 and a void VD2 disposed in the first region R1. The void VD1 may be disposed in the second conductive layer T2 located in the opening OP2, and the void VD2 may be disposed in the second conductive layer T2 located in the first region R1. In some embodiments, a top width of the void VD1 may be less than a bottom width of the void VD1, a top width of the void VD2 may be less than a bottom width of the void VD2, and the void VD1 and the void VD2 may directly contact the first conductive layer T1, respectively, but not limited thereto. In addition, the void VD2 located in the first region R1 is lower than the first supporting layer 32 in the vertical direction D1, a part of the void VD1 located in the opening OP2 may be lower than the first supporting layer 32 in the vertical direction D1, and another part of the void VD1 may be higher than the first supporting layer 32 and lower than the second supporting layer 36 in the vertical direction D1. In addition, a length of each of the voids VD in the vertical direction D1 may be greater than a length of this void VD in the horizontal directions (such as the horizontal direction D2) for reducing the chance of the void VD directly contacting the first conductive layer T1 in the horizontal directions, and the influence of the voids on the contact area between the second conductive layer T2 and the first conductive layer T1 may be reduced accordingly.

In some embodiments, the memory device 101 may further include a third supporting layer 38 and an electrically conductive layer CL. The third supporting layer 38 may be disposed on the second supporting layer 36, and the electrically conductive layer CL may be disposed on the second conductive layer T2. The third supporting layer 38 may support the sidewall of the bottom electrode BE laterally, and the dielectric layer DL and the top electrode TE may be partly disposed on the third supporting layer 38 in the vertical direction D1. The third supporting layer 38 and the second supporting layer 36 may be directly connected with each other for constituting a second supporting structure SS2, and the first supporting layer 32 may be regarded as at least a portion of a first supporting structure SS1, but not limited thereto. In some embodiments, the first supporting structure SS1 may be composed of multiple layers of supporting materials according to some design considerations. For example, the first supporting structure SS1 may include a single layer or multiple layers of materials, such as nitride (silicon nitride, for example), oxide (silicon oxide, for example), or other suitable materials, the third supporting layer 38 may include carbon doped insulation materials, such as carbon doped silicon nitride (SiCN), carbon doped silicon oxide (SiOC), or other suitable insulation materials, and the second supporting layer 36 may include insulation materials without carbon dopants, such as silicon nitride, silicon oxide, silicon oxynitride, or other suitable insulation materials, but not limited thereto. In some embodiments, the electrically conductive layer CL may include aluminum, tungsten, titanium, copper, titanium aluminide, or other suitable electrically conductive materials with low electrical resistivity. In addition, a part of the second conductive layer T2 of the top electrode TE may cover the first conductive layer T1, the dielectric layer DL, the bottom electrode BE, the first supporting layer 32, the second supporting layer 36, and the third supporting layer 38 in the vertical direction D1, and a top surface of the second conductive layer T2 may be higher than the first conductive layer T1, the dielectric layer DL, the bottom electrode BE, and the third supporting layer 38 in the vertical direction D1 accordingly. In some embodiments, each of the bottom electrodes BE, the top electrode TE, and the dielectric layer DL sandwiched between this bottom electrode BE and the top electrode TE may form a capacitor unit, the bottom electrodes BE may be located corresponding to different capacitor units, and the top electrode TE may be shared by the capacitor units, but not limited thereto.

In some embodiments, the node contact structure 22 may include electrically conductive materials, such as aluminum, tungsten, titanium, copper, titanium aluminide, or other suitable electrically conductive materials with low electrical resistivity, and the isolation structure 24 may include a single layer or multiple layers of insulation materials, such as oxide, nitride, carbon doped nitride, carbide, or other suitable insulation materials. In some embodiments, the node contact structure 22 may include a single electrically conductive material layer or multiple layers of electrically conductive materials, such as a multi-layer electrically conductive structure composed of cobalt silicide (CoSi), titanium, titanium nitride, and tungsten stacked with one another, but not limited thereto. The bottom electrode BE may include a single layer or multiple layers of electrically conductive materials, such as doped silicon, tungsten, copper, titanium nitride, or other suitable electrically conductive materials, and the dielectric layer DL may include a high dielectric constant metal oxide layer, such as TaO, TaAlO, TaON, AlO, AlSiO, HfO, HfSiO, ZrO, ZrSiO, TiO, TiAlO, BST ((Ba,Sr)TiO), STO (SrTiO), BTO (BaTiO), PZT (Pb(Zr,Ti)O), (Pb,La)(Zr,Ti)O, Ba(Zr,Ti)O, Sr(Zr,Ti)O, a combination of the above-mentioned materials, or other suitable dielectric materials. In some embodiments, the material composition of the first conductive layer T1 of the top electrode TE may be different from the material composition of the second conductive layer T2 of the top electrode TE. For example, the first conductive layer T1 may include titanium nitride, tantalum nitride, or other suitable electrically conductive materials, and the second conductive layer T2 may include a doped silicon germanium material (such as boron-doped silicon germanium) or other suitable electrically conductive materials, but not limited thereto.

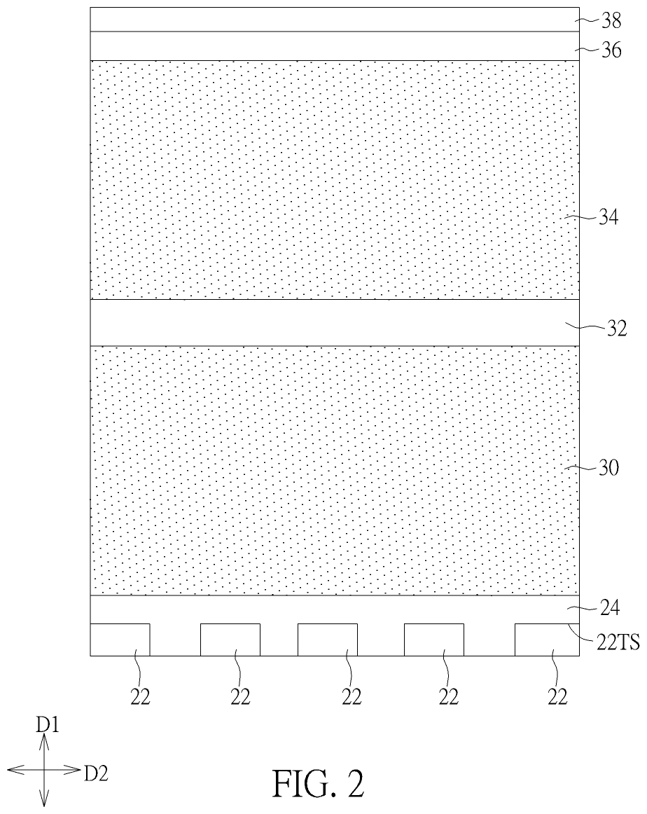

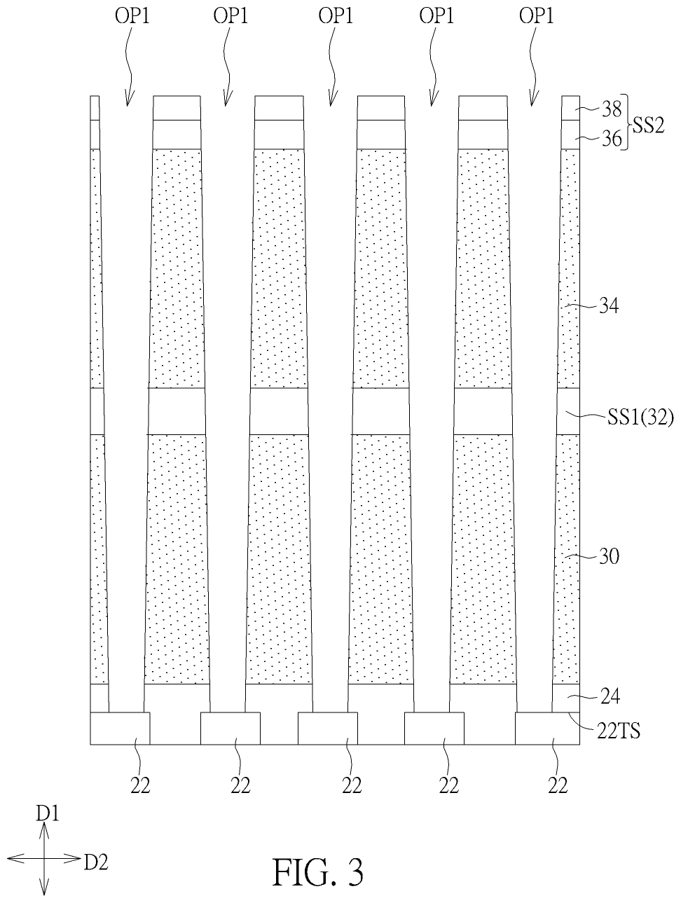

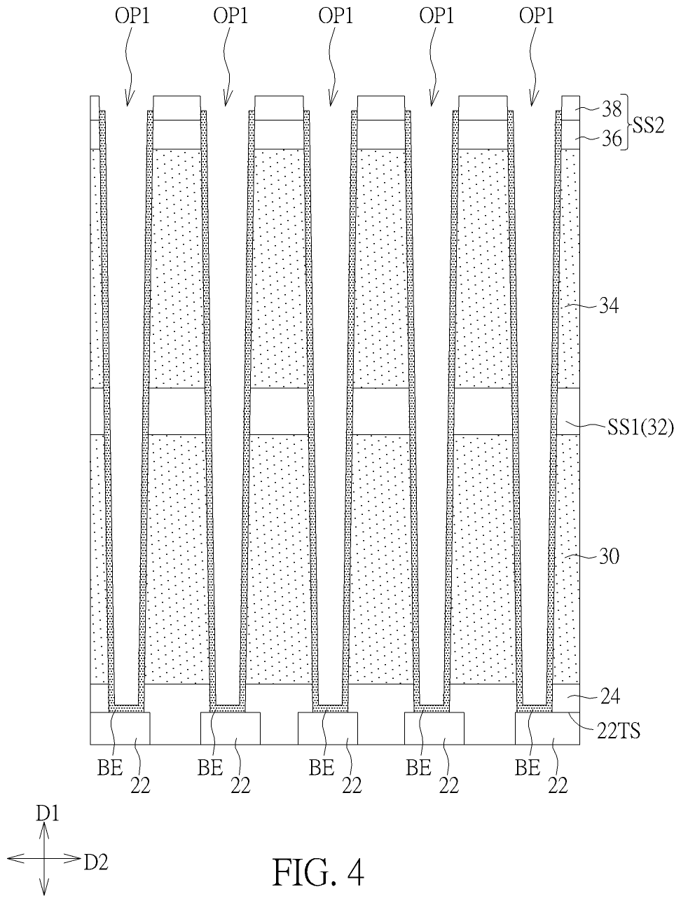

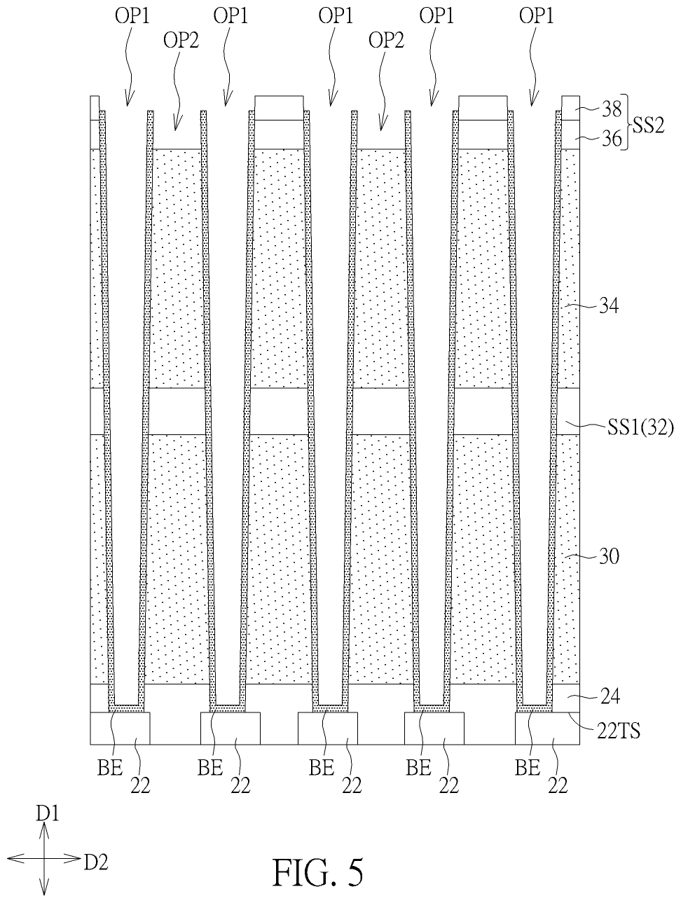

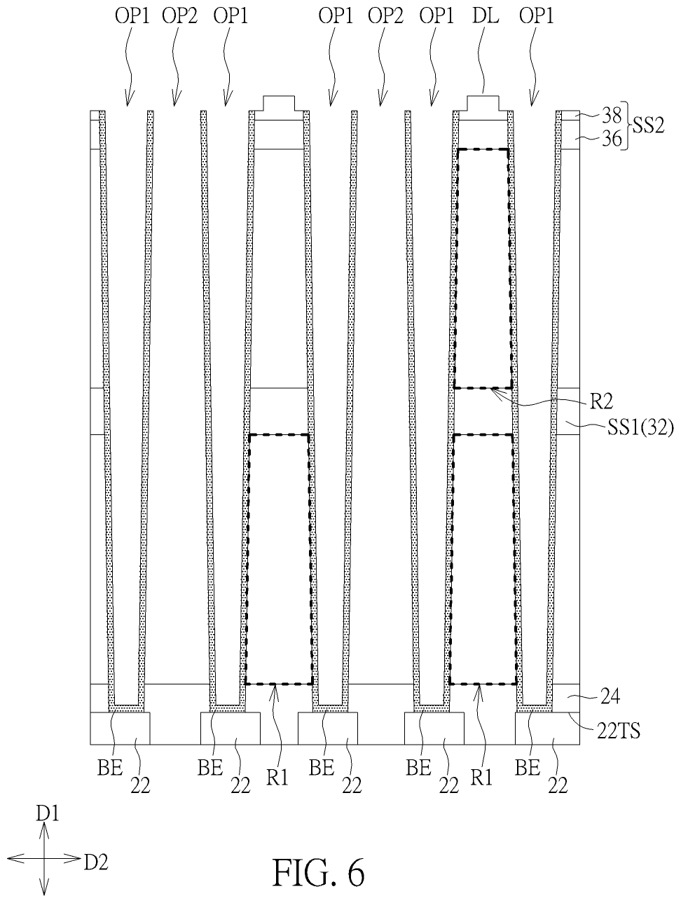

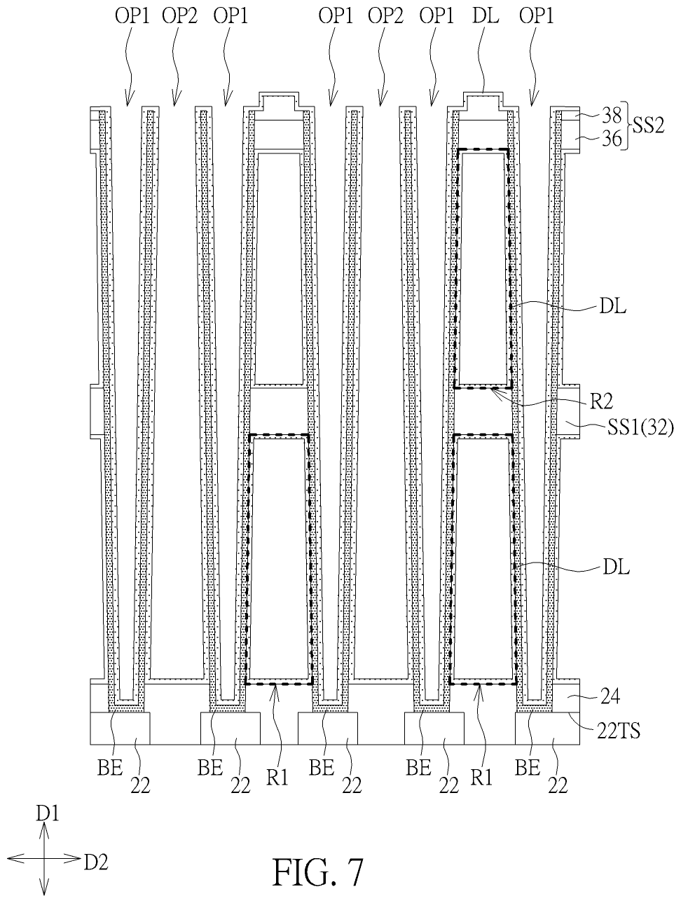

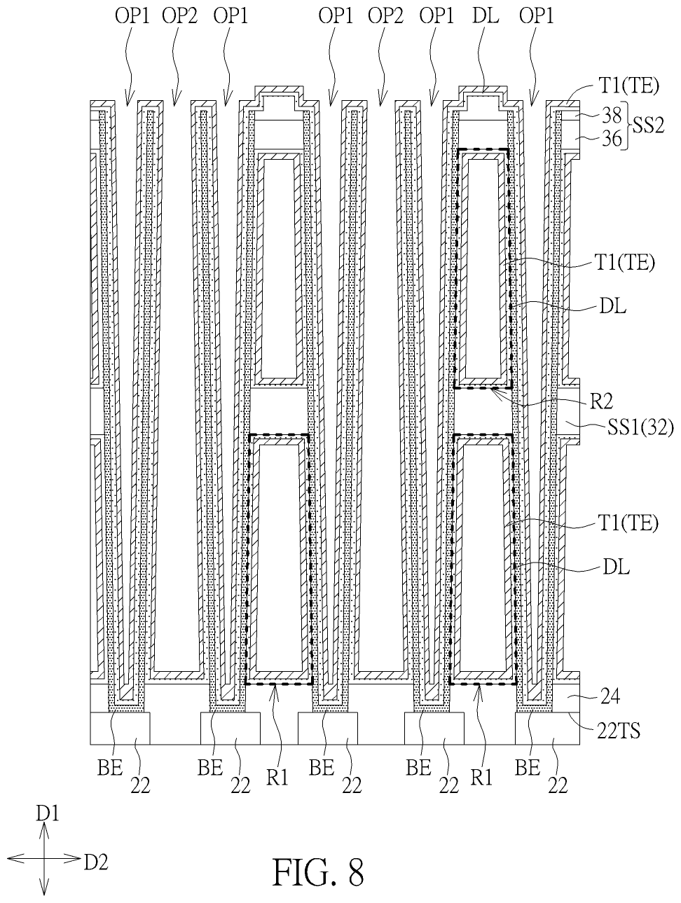

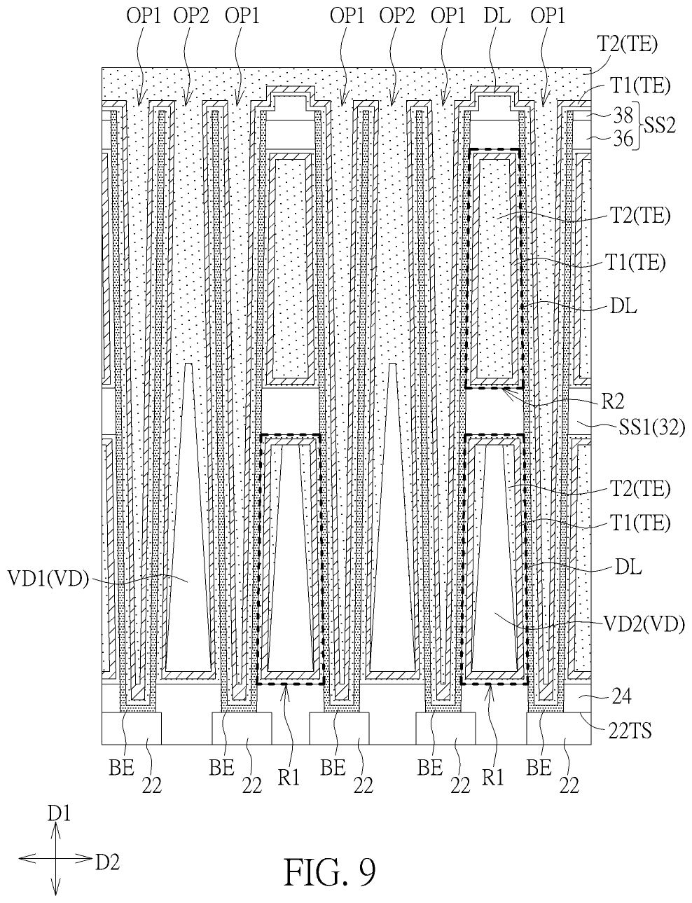

Please refer to FIGS. 1-9. FIGS. 2-9 are schematic drawings illustrating a manufacturing method of a memory device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, and FIG. 9 is a schematic drawing in a step subsequent to FIG. 8. In some embodiments, FIG. 1 may be regarded as a schematic drawing in a step subsequent to FIG. 9, but not limited thereto. As shown in FIG. 1, a manufacturing method of a memory device is provided in this embodiment and includes the following steps. The capacitor structure CP is formed on the node contact structure 22. The capacitor structure CP includes the bottom electrode BE, the top electrode TE, and the dielectric layer DL. The bottom electrode BE is disposed on the node contact structure 22, the top electrode TE is disposed on the bottom electrode BE, and the dielectric layer DL is disposed between the top electrode TE and the bottom electrode BE. The top electrode TE includes the first conductive layer T1 and the second conductive layer T2. The first conductive layer T1 is disposed on the dielectric layer DL, the second conductive layer T2 is disposed on the first conductive layer T1, and at least one void VD is disposed in the second conductive layer T2.

Specifically, the manufacturing method of the memory device in this embodiment may include but is not limited to the following steps. As shown in FIG. 2, a plurality of the node contact structures 22 may be formed, and the isolation structure 24 may be formed. The isolation structure 24 may be located adjacent to the node contact structures 22, and a part of the isolation structure 24 may cover each of the node contact structures 22. Subsequently, a first sacrificial material layer 30 may be formed on the isolation structure 24, the first supporting layer 32 may be formed on the first sacrificial material layer 30, a second sacrificial material layer 34 may be formed on the first supporting layer 32, the second supporting layer 36 may be formed on the second sacrificial material layer 34, and the third supporting layer 38 may be formed on the second supporting layer 36. The first sacrificial material layer 30 and the second sacrificial material layer 34 may respectively include a single layer or multiple layers of oxide materials, such as silicon oxide, tetraethyl orthosilicate (TEOS), boro-phospho-silicate-glass (BPSG), or other sacrificial materials having the required etching selectivity with the material of the supporting layers. As shown in FIGS. 2-3, a plurality of the openings OP1 may then be formed, each of the openings OP1 may penetrate through the third supporting layer 38, the second supporting layer 36, the second sacrificial material layer 34, the first supporting layer 32, and the first sacrificial material layer 30 in the vertical direction D1, and each of the openings OP1 may expose a part of the corresponding node contact structure 22. In other words, the first sacrificial material layer 30, the first supporting layer 32, the second sacrificial material layer 34, the second supporting layer 36, and the third supporting layer 38 may be formed before the step of forming the openings OP1. After the step of forming the openings OP1, the first supporting layer 32 may be regarded as the first supporting structure SS1, and the second supporting layer 36 and the third supporting layer 38 may be regarded as the second supporting structure SS2. In some embodiments, a thickness of the second supporting structure SS2 in the vertical direction D1 may be greater than a thickness of the first supporting structure SS1 in the vertical direction D1 for ensuring the supporting effect of the supporting structures and reducing the influence of the first supporting structure SS1 on the area of the capacitor subsequently formed, but not limited thereto.

As shown in FIGS. 3-4, the bottom electrodes BE may be formed in the openings OP1, and the bottom electrode BE may cover the inner sidewall of the opening OP1 and be electrically connected with the corresponding node contact structure 22. The third supporting layer 38, the second supporting layer 36, the second sacrificial material layer 34, the first supporting layer 32, and the first sacrificial material layer 30 may be located on the sidewall of the bottom electrode BE. In some embodiments, the top portion of the bottom electrode BE may be slightly lower than the top portion of the third supporting layer 38 by over etching or over polishing in the step of forming the bottom electrodes BE, and the top portion of the bottom electrode BE may be higher than the top portion of the second supporting layer 36 in the vertical direction D1, but not limited thereto. As shown in FIGS. 4-5, in some embodiments, after the step of forming the bottom electrodes BE, the openings OP2 may be formed by removing a part of the third supporting layer 38 and a part of the second supporting layer 36, and the opening OP2 may expose a part of the second sacrificial material layer 34. Subsequently, as shown in FIGS. 5-6, the first sacrificial material layer 30 and the second sacrificial material layer 34 may be removed after the step of forming the openings OP2, and the first supporting layer 32, the second supporting layer 36, and the third supporting layer 38 may still support the sidewall of the bottom electrode BE laterally after the first sacrificial material layer 30 and the second sacrificial material layer 34 are removed. In some embodiments, the openings OP2 may be used to enhance the efficiency of the step of removing the first sacrificial material layer 30 and the second sacrificial material layer 34, but not limited thereto.

As shown in FIGS. 5-9, the opening OP2 may extend downwards for exposing the first supporting layer 32 corresponding to the opening OP2 by etching the second sacrificial material layer 34 located under the opening OP2. In some embodiments, an isotropic etching process, such as a wet etching process, may be used to completely remove the second sacrificial material layer 34 exposed by the openings OP2 and other portions of the second sacrificial material layer 34 covered by the second supporting layer 36, but not limited thereto. Subsequently, the opening OP2 may further extend downwards and expose the first sacrificial material layer 30 by removing the first supporting layer 32 corresponding to the openings OP with an etching process. In some embodiments, the etching process configured to remove the first supporting layer 32 located corresponding to the openings OP2 may include an anisotropic etching process, such as a dry etching process, for removing the first supporting layer 32 corresponding to the openings OP2 and keeping the other portions of the first supporting layer 32 covered by the second supporting layer 36. Subsequently, the opening OP2 may extend to the isolation structure 24 by removing the first sacrificial material layer 30 located under the openings OP2 with an etching process, and the sidewall of the opening OP2 may expose a part of the sidewall of the bottom electrode BE. In some embodiments, an isotropic etching process, such as a wet etching process, may be used to completely remove the first sacrificial material layer 30 exposed by the openings OP2 and other portions of the first sacrificial material layer 30 covered by the first supporting layer 32, but not limited thereto. In some embodiments, a part of the third supporting layer 38 may be removed in the steps of etching the first sacrificial material layer 30 and the second sacrificial material layer 34 because the third supporting layer 38 is located at the topmost surface. For example, the portion of the third supporting layer 38 without being covered by the bottom electrode BE may be etching laterally, and a top width of the third supporting layer 38 located between the adjacent bottom electrodes BE may be less than a bottom width of the third supporting layer 38 located between the adjacent bottom electrodes BE accordingly, but not limited thereto.

As shown in FIGS. 5-9, after the first sacrificial material layer 30 and the second sacrificial material layer 34 are removed, the dielectric layer DL and the top electrode TE may be formed. The dielectric layer DL and the top electrode TE may be partly formed between the first supporting layer 32 and the isolation structure 24, partly formed between the second supporting layer 36 and the first supporting layer 32, partly formed in the openings OP1, and partly formed in the openings OP2. As shown in FIG. 6, in some embodiments, the first region R1 may be regarded as a region located between the first supporting layer 32 and the isolation structure 24 in the vertical direction D1 and located between the adjacent bottom electrodes BE in the horizontal direction, and the second region R2 may be regarded as a region located between the second supporting layer 36 and the first supporting layer 32 in the vertical direction D1 and located between the adjacent bottom electrodes BE in the horizontal direction. As shown in FIG. 7, the dielectric layer DL may be deposited globally, and the dielectric layer DL may conformally cover the exposed surface of the bottom electrodes BE, the exposed surface of the third supporting layer 38, the exposed surface of the second supporting layer 36, the exposed surface of the first supporting layer 32, and the exposed surface of the isolation structure 24. Subsequently, the first conductive layer T1 may be deposited on the dielectric layer DL, and the first conductive layer T1 may conformally cover the dielectric layer DL. Afterwards, the second conductive layer T2 may be formed on the first conductive layer T1. The openings OP1, the openings OP2, the first regions R1, and the second regions R2 may be filled with a part of the second conductive layer T2, and the second conductive layer T2 may be partly formed outside the openings OP1, the openings OP2, the first regions R1, and the second regions R2. In some embodiments, the first conductive layer T1 may be formed by a suitable deposition process (such as a chemical vapor deposition process, but not limited thereto) with better step coverage for ensuring the condition of the first conductive layer T1 covering the dielectric layer DL, and the second conductive layer T2 may be formed with better gap-filling performance and/or a deposition rate higher than that of the first conductive layer T1 for reducing the process time of forming the top electrode TE, but not limited thereto.

In some embodiments, the second conductive layer T2 may be formed by a suitable deposition process (such as a chemical vapor deposition process, but not limited thereto), and the void VD described above may be formed in the second conductive layer T2 by this deposition process. The void VD may be formed and/or the position and the shape of the void VD may be controlled by controlling the process conditions of the deposition process, such as controlling the variation of the deposition rate of the deposition process. For example, the void VD may be formed at the bottommost part of the second conductive layer T2 by using process conditions for higher deposition rate in the front section of the deposition process, and the process conditions for lower deposition rate may be applied in the middle section and the back section of the deposition process for completing the step of forming the second conductive layer T2, but not limited thereto. In some embodiments, the void VD in the second conductive layer T2 may be controlled and adjusted by other suitable approaches also (such as an annealing process performed after the deposition process, but not limited thereto). Because the voids VD formed in the second conductive layer T2 are acceptable, the process time of the deposition process for forming the second conductive layer T2 may be reduced, the throughput of the related manufacturing equipment may be improved, the manufacturing capacity may be enhanced, and/or the manufacturing cost may be reduced relatively. As shown in FIG. 9 and FIG. 1, after the step of forming the top electrode TE, the electrically conductive layer CL may be formed on the top electrode TE for forming the memory device 101. It is worth noting that the method of forming the capacitor structure CP in this embodiment may include but is not limited to the steps illustrated in FIGS. 2-9 described above, and the capacitor structure CP with the void VD formed in the top electrode TE may also be formed by other suitable approaches according to some design considerations.

The following description will detail the different embodiments of the present invention. To simplify the description, the following description will detail the dissimilarities among different embodiments and the identical features will not be redundantly described. In addition, identical components in each of the following embodiments of the present invention are marked with identical symbols for making it easier for comparing the embodiments more conveniently.

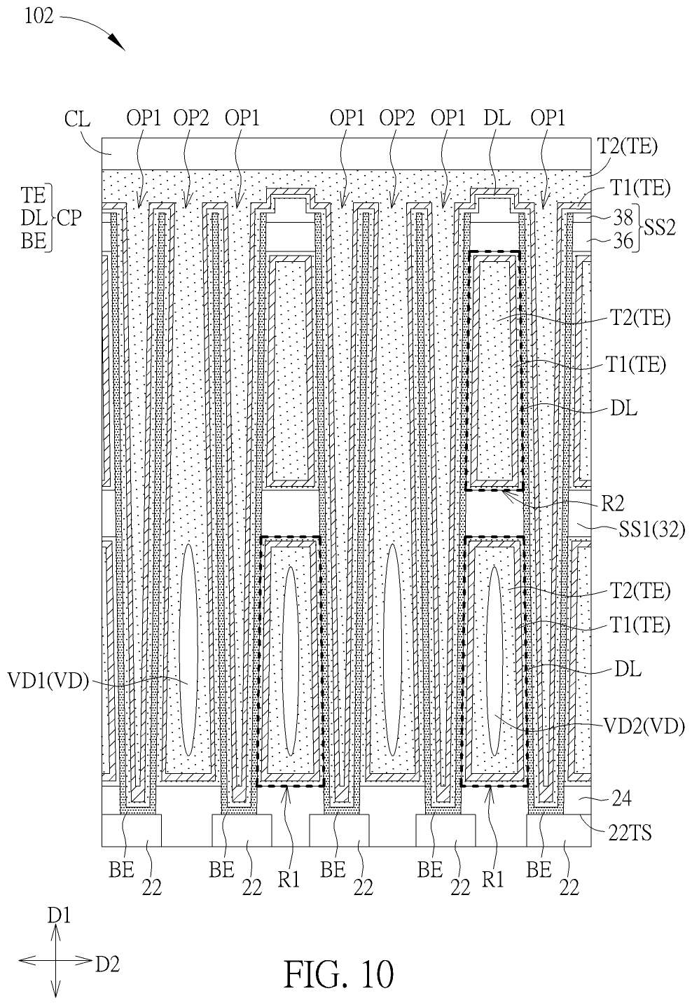

Please refer to FIG. 10. FIG. 10 is a schematic drawing illustrating a memory device 102 according to a second embodiment of the present invention. In the memory device 102, the void VD (such as the void VD1 formed in the opening OP2 and/or the void VD2 formed in the first region R1) may be separated with the first conductive layer T1, and the void VD may be encompassed by the second conductive layer T2. In other words, the void VD may not directly contact the first conductive layer T1 for further lowering the influence of the void VD on the connection between the first conductive layer T1 and the second conductive layer T2. In addition, the void VD may be lower than the top of the first supporting layer 32 in the vertical direction D1, the void VD may have an oval shape in a cross-sectional diagram of the memory device 102, and the length of the void VD in the vertical direction D1 may be greater than the length of the void VD in the horizontal direction D2, but not limited thereto.

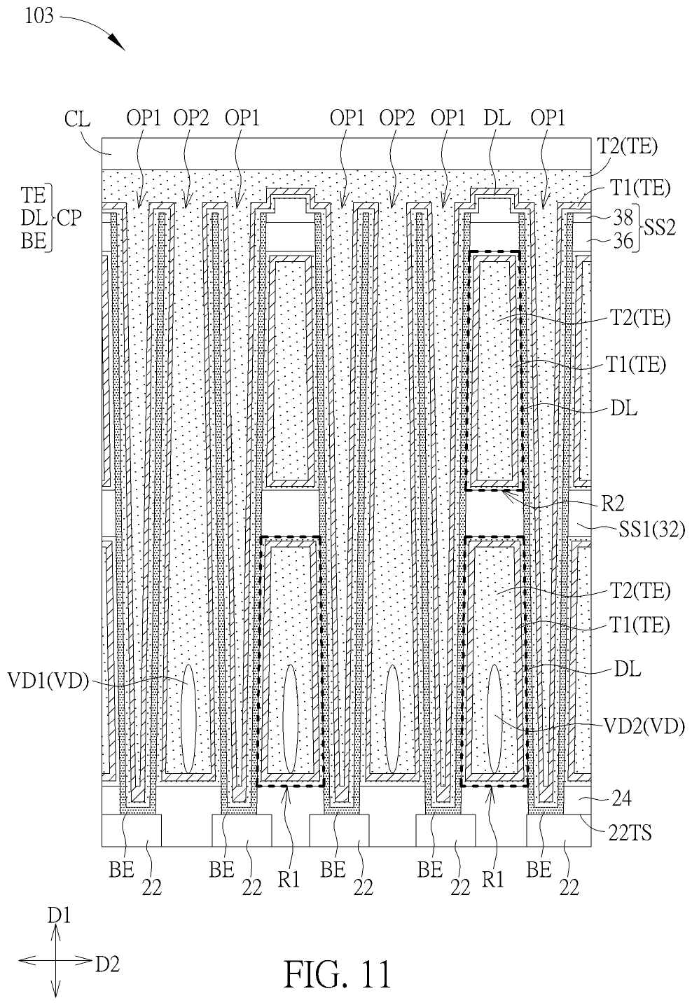

Please refer to FIG. 11. FIG. 11 is a schematic drawing illustrating a memory device 103 according to a third embodiment of the present invention. In the memory device 103, the void VD (such as the void VD1 formed in the opening OP2 and/or the void VD2 formed in the first region R1) have an oval shape in a cross-sectional diagram of the memory device 103, and the length of the void VD in the vertical direction D1 may be greater than the length of the void VD in the horizontal direction D2. In addition, the void VD may directly contact the first conductive layer T1, such as directly contacting the first conductive layer T1 located at the bottom of the opening OP2 and/or the first conductive layer T1 located at the bottom of the first region R1.

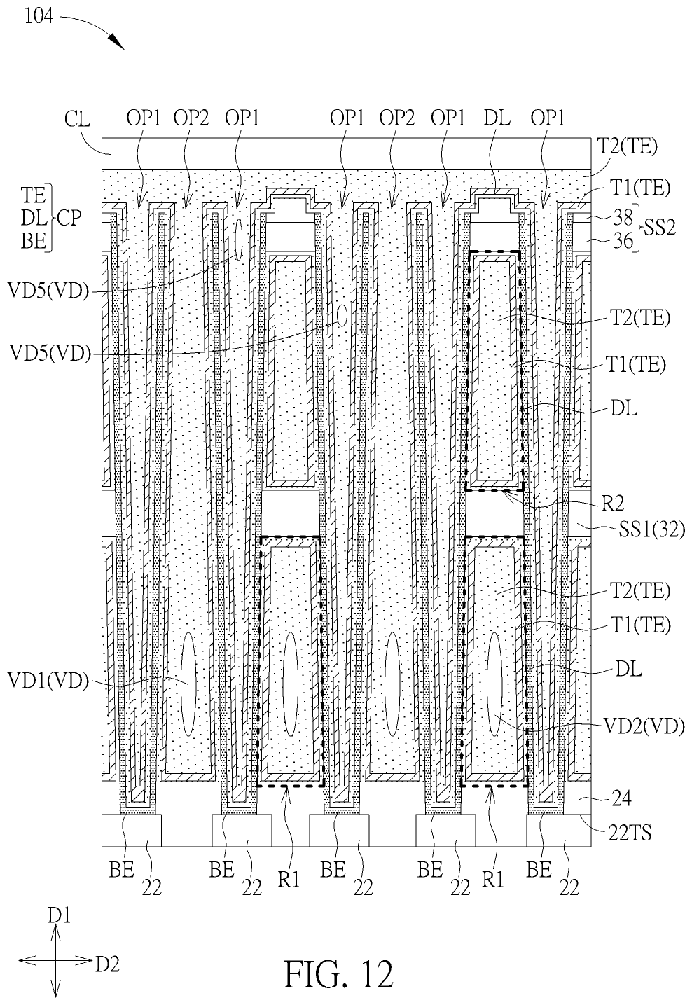

Please refer to FIG. 12. FIG. 12 is a schematic drawing illustrating a memory device 104 according to a fourth embodiment of the present invention. In the memory device 104, the void VD (such as the void VD1 formed in the opening OP2 and/or the void VD2 formed in the first region R1) may be separated from the first conductive layer T1, and the void VD may be encompassed by the second conductive layer T2. In addition, the void VD (such as the void VD1 and the void VD2) may be lower than the bottom of the first supporting layer 32 in the vertical direction D1, the void VD may have an oval shape in a cross-sectional diagram of the memory device 104, and the length of the void VD in the vertical direction D1 may be greater than the length of the void VD in the horizontal direction D2, but not limited thereto. In some embodiments, the void VD (such as a void VD5) may be disposed above one of the pad structures (one of the node contact structures 22) in the vertical direction D1, and the void VD5 may be located within the opening OP1. In some embodiments, the void VD5 may be higher than the first supporting layer 32 and lower than the second supporting layer 36 in the vertical direction D1, but not limited thereto.

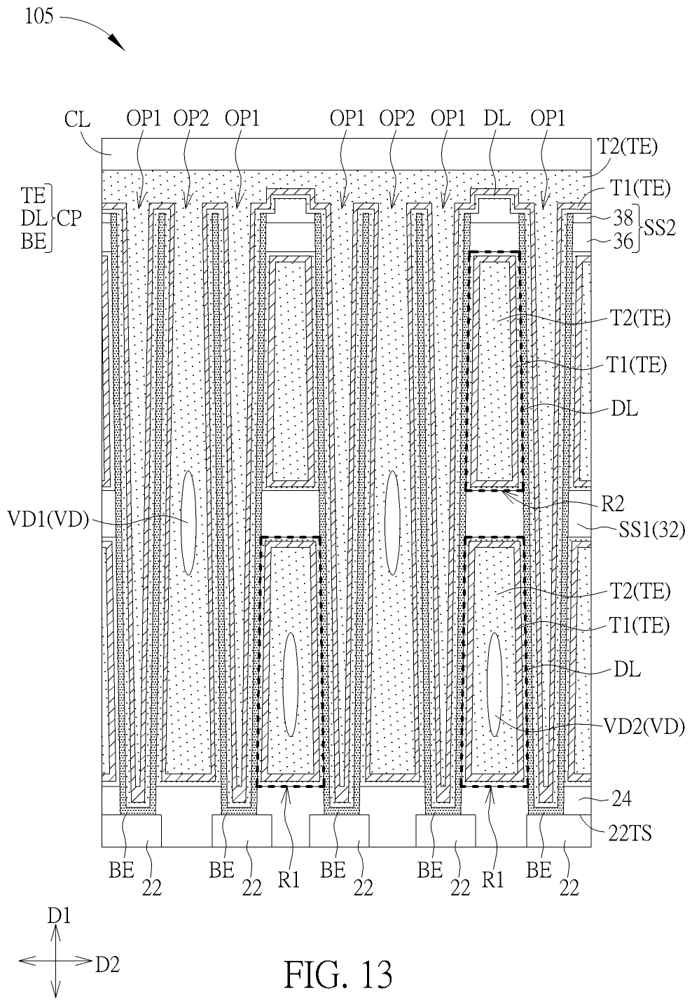

Please refer to FIG. 13. FIG. 13 is a schematic drawing illustrating a memory device 105 according to a fifth embodiment of the present invention. In the memory device 105, the void VD (such as the void VD1 formed in the opening OP2 and/or the void VD2 formed in the first region R1) may be separated from the first conductive layer T1, and the void VD may be encompassed by the second conductive layer T2. The void VD may have an oval shape in a cross-sectional diagram of the memory device 105, and the length of the void VD in the vertical direction D1 may be greater than the length of the void VD in the horizontal direction D2, but not limited thereto. In addition, a part of the void VD1 located in the opening OP2 may be higher than the top of the first supporting layer 32 and lower than the bottom of the second supporting layer 36 in the vertical direction D1.

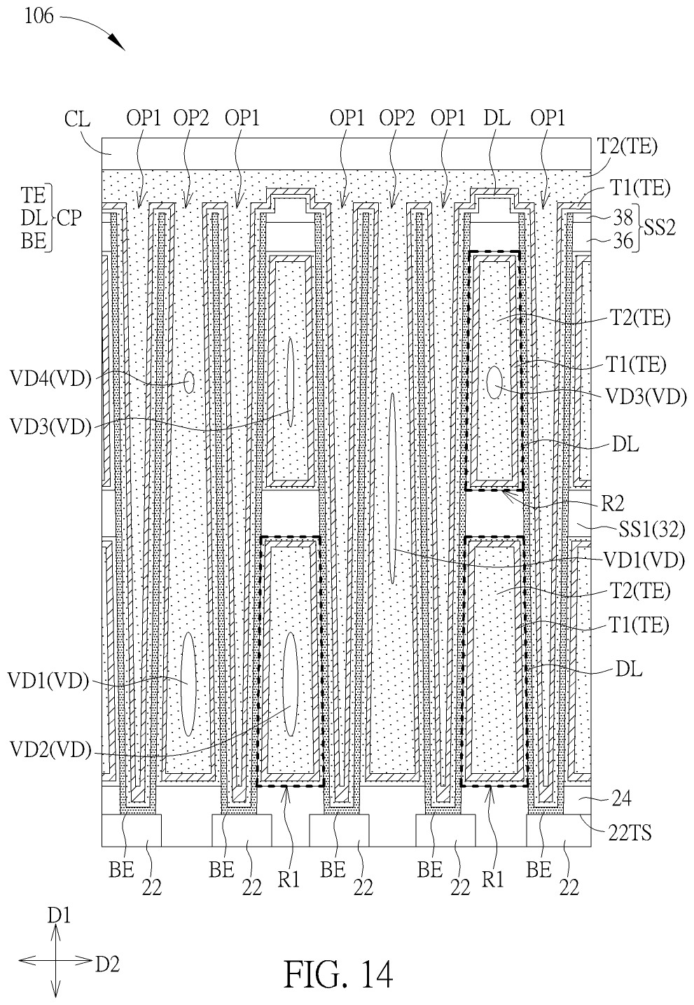

Please refer to FIG. 14. FIG. 14 is a schematic drawing illustrating a memory device 106 according to a sixth embodiment of the present invention. In the memory device 106, the voids VD may further include a void VD3 formed in the second conductive layer T2 located in the second region R2, and the void VD3 may be disposed and/or formed in the second conductive layer T2 of the top electrode TE located between the second supporting layer 36 and the first supporting layer 32. In some embodiments, because of the influence of the shape of the opening OP1, the dimension of the void VD3 formed in the second region R2 may be smaller than the dimension of the void VD2 formed in the first region R1, but not limited thereto. In addition, the void VD disposed between two of the bottom electrodes BE (such as the void VD formed in the opening OP2) may include a first void (such as the void VD1) and a second void (such as a void VD4) separated from each other, the void VD4 may be located above the void VD1 in the vertical direction D1, and the dimension of the void VD4 may be smaller than the dimension of the void VD1. In some embodiments, the void VD4 may be higher than the top of the first supporting layer 32 and lower than the bottom of the second supporting layer 36 in the vertical direction D1, and the void VD1 may be partially higher than the top of the first supporting layer 32 in the vertical direction D1 or be completely lower than the bottom of the first supporting layer 32 in the vertical direction D1.

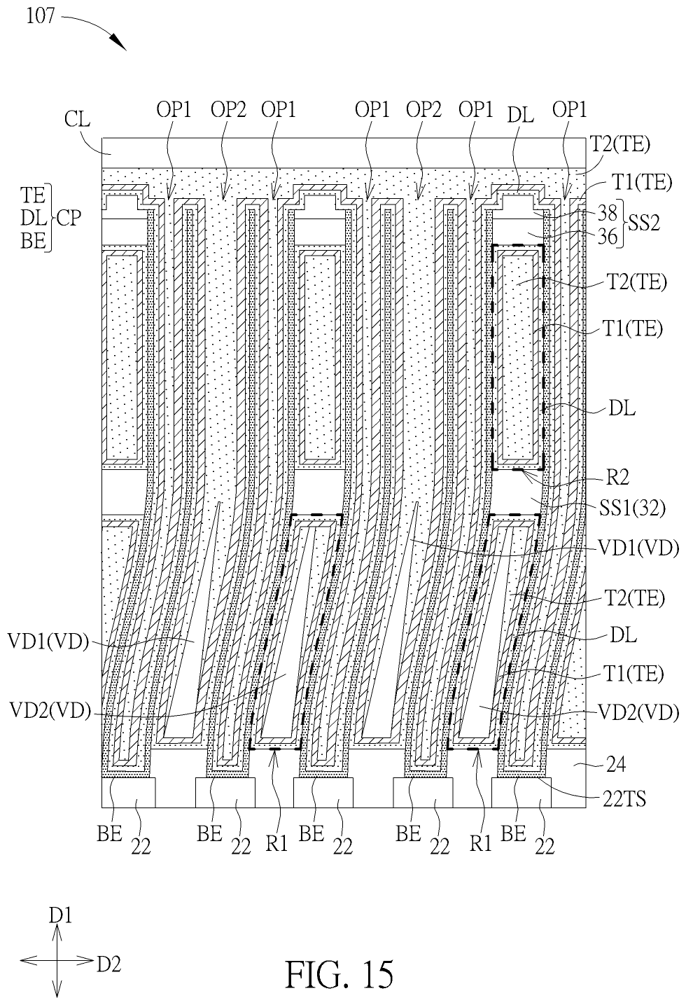

Please refer to FIG. 15. FIG. 15 is a schematic drawing illustrating a memory device 107 according to a seventh embodiment of the present invention. In the memory device 107, the voids VD may be formed by the influence of the bending condition of some areas. Due to the change of local support force and stress, some areas of the capacitor structure are deformed and bent, which makes it easier to form the voids VD in the second conductive layer T2 during the subsequent step of forming the second conductive layer T2, but not limited thereto. The above-mentioned deformation bending phenomenon may also occur after the formation of the second conductive layer T2, and this deformation bending phenomenon may lead to the formation of the voids VD in the second conductive layer T2 of the top electrode TE.

To summarize the above descriptions, in the memory device and the manufacturing method thereof according to the present invention, the void may be disposed in the capacitor structure, and the void is located in one electrically conductive layer of the multi-layer structure of the top electrode for reducing negative influence of the void on the top electrode while increasing the manufacturing throughput of the manufacturing method.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A capacitor device, comprising:
pad structures;
bottom electrodes disposed on the pad structures, respectively;
a top electrode disposed on the bottom electrodes; and
a dielectric layer disposed between the top electrode and the bottom electrodes, wherein the top electrode comprises at least one void.

2. The capacitor device according to claim 1, wherein the top electrode is partly disposed between any two of the bottom electrodes, and the at least one void is disposed between the two of the bottom electrodes.

3. The capacitor device according to claim 2, wherein the at least one void disposed between the two of the bottom electrodes comprises a first void and a second void separated from each other, and the second void is smaller than the first void.

4. The capacitor device according to claim 1, wherein the top electrode comprises:
a first conductive layer disposed on the dielectric layer; and
a second conductive layer disposed on the first conductive layer, wherein the at least one void is disposed in the second conductive layer, and the at least one void directly contact the first conductive layer.

5. The capacitor device according to claim 1, wherein the top electrode comprises:
a first conductive layer disposed on the dielectric layer; and
a second conductive layer disposed on the first conductive layer, wherein the at least one void is disposed in the second conductive layer, the at least one void is separated from the first conductive layer, and the at least one void is encompassed by the second conductive layer.

6. The capacitor device according to claim 1, further comprising:
an isolation structure disposed adjacent to the pad structures;
a first supporting layer disposed above the isolation structure in a vertical direction, wherein a part of the top electrode is disposed between the first supporting layer and the isolation structure; and
a second supporting layer disposed above the first supporting layer in the vertical direction, wherein another part of the top electrode is disposed between the second supporting layer and the first supporting layer.

7. The capacitor device according to claim 6, wherein the at least one void is disposed in the part of the top electrode located between the first supporting layer and the isolation structure.

8. The capacitor device according to claim 6, wherein the at least one void is lower than the first supporting layer in the vertical direction.

9. The capacitor device according to claim 6, wherein at least a part of the at least one void is higher than the first supporting layer and lower than the second supporting layer in the vertical direction.

10. The capacitor device according to claim 6, wherein the at least one void is disposed in the another part of the top electrode located between the second supporting layer and the first supporting layer.

11. The capacitor device according to claim 1, wherein a top width of the at least one void is less than a bottom width of the at least one void.

12. The capacitor device according to claim 1, wherein a length of the at least one void in a vertical direction is greater than a length of the at least one void in a horizontal direction.

13. The capacitor device according to claim 1, wherein the at least one void is disposed above one of the pad structures in a vertical direction.

14. A manufacturing method of a capacitor device, comprising:
forming a bottom electrode on a pad structure; and
forming a top electrode and a dielectric layer, wherein the top electrode is disposed on the bottom electrode, the dielectric layer is disposed between the top electrode and the bottom electrode, and the top electrode comprises at least one void.

15. The manufacturing method of the capacitor device according to claim 14, further comprising:
forming an isolation structure, wherein the isolation structure is located adjacent to the pad structure, and a part of the isolation structure covers the pad structure;
forming a first sacrificial material layer on the isolation structure;
forming a first supporting layer on the first sacrificial material layer;
forming an opening penetrating through the first supporting layer and the first sacrificial material layer in a vertical direction, wherein the bottom electrode is formed in the opening; and
removing the first sacrificial material layer after the bottom electrode is formed, wherein the first supporting layer supports a sidewall of the bottom electrode laterally, the dielectric layer and the top electrode are formed after the first sacrificial material layer is removed, and the dielectric layer and the top electrode are partly formed between the first supporting layer and the isolation structure.

16. The manufacturing method of the capacitor device according to claim 15, wherein the top electrode comprises:
a first conductive layer disposed on the dielectric layer; and
a second conductive layer disposed on the first conductive layer, wherein the at least one void is formed in the second conductive layer of the top electrode located between the first supporting layer and the isolation structure.

17. The manufacturing method of the capacitor device according to claim 15, wherein the at least one void is lower than the first supporting layer in the vertical direction.

18. The manufacturing method of the capacitor device according to claim 15, further comprising:
forming a second sacrificial material layer on the first supporting layer and forming a second supporting layer on the second sacrificial material layer before the opening is formed, wherein the opening further penetrates through the second supporting layer and the second sacrificial material layer in the vertical direction; and
removing the second sacrificial material layer after the bottom electrode is formed, wherein the second supporting layer supports the sidewall of the bottom electrode laterally, and the dielectric layer and the top electrode are partly formed between the second supporting layer and the first supporting layer.

19. The manufacturing method of the capacitor device according to claim 18, wherein the top electrode comprises:
a first conductive layer disposed on the dielectric layer; and
a second conductive layer disposed on the first conductive layer, wherein the at least one void is formed in the second conductive layer of the top electrode located between the second supporting layer and the first supporting layer.

20. The manufacturing method of the capacitor device according to claim 18, wherein at least a part of the at least one void is higher than the first supporting layer and lower than the second supporting layer in the vertical direction.
